(19) United States
(12) Patent Application Publication
(10) Pub. No.: US 2025/0275444 A1
(43) Pub. Date: Aug. 28, 2025

(54) COVER LAYER FOR DISPLAY DEVICE AND DISPLAY DEVICE INCLUDING COVER LAYER

(71) Applicant: Samsung Display Co., LTD., Yongin-si (KR)

(72) Inventor: Jong Hwan CHO, Yongin-si (KR)

(21) Appl. No.: 18/895,637

(22) Filed: Sep. 25, 2024

(30) Foreign Application Priority Data
Feb. 23, 2024 (KR) 10-2024-0026453

(51) Int. Cl. H10K 59/80; C08J 7/04; C09D 5/00; C09D 183/06; C09D 183/08; H10K 102/00

(52) U.S. Cl. CPC H10K 59/8791; C08J 7/042; C09D 5/006; C09D 183/06; C09D 183/08; H10K 59/873; C08J 2367/02; C08J 2483/06; C08J 2483/08; H10K 2102/311

(57) ABSTRACT

A cover layer for a display device includes: a first layer forming a base; a second layer disposed on the first layer, the second layer including a random-type silsesquioxane including an ether functional group; and a third layer disposed on the second layer. The third layer includes a random-type silsesquioxane including a perfluoroalkyl functional group and a cage-type silsesquioxane including a fluorine-based ether functional group.

This application claims priority to Korean Patent Application No. 10-2024-0026453 filed on Feb. 23, 2024, and all the benefits accruing therefrom under 35 U.S.C. § 119, the content of which in its entirety is herein incorporated by reference.

### BACKGROUND

### 1. Field

The present disclosure generally relates to a cover layer for a display device and a display device including the cover layer.

### 2. Description of the Related Art

With the development of information technologies, the importance of a display device which is a connection medium between a user and information increases.

A structure for improving external visibility in a display device is desired. For example, controlling external light reflectivity for improving the external visibility is desired.

A display device may be applicable to various product groups. Accordingly, a display device having excellent characteristics in various properties such as, for example, flexibility is desired.

### SUMMARY

Embodiments provide a cover layer and a display device including a cover layer, in which external light reflectivity is controlled, such that visibility is improved.

Embodiments also provide a cover layer and a display device including a cover layer, which have excellent mechanical characteristics and flexibility.

In accordance with an aspect of the present disclosure, provided is a cover layer for a display device, the cover layer including: a first layer forming a base; a second layer disposed on the first layer, the second layer including a random-type silsesquioxane including an ether functional group; and a third layer disposed on the second layer, the third layer including a random-type silsesquioxane including a perfluoroalkyl functional group and a cage-type silsesquioxane including a fluorine-based ether functional group.

The first layer may include poly(ethylene terephthalate) (PET).

The ether functional group of the second layer may include an ethyl-methyl-ether group (C₂H₅OCH₃), an ether group (C₃OH₁₁) including five carbons, or an ether group (C₄OH₉) including four carbons.

The perfluoroalkyl functional group of the third layer may include CF₂CF₂CF₂CF₃, CF₂CF₂CF₃ or CF₂CF₂CF₂CF₂CF₃.

The fluorine-based ether functional group of the third layer may include CF₂OCF₂CF₂CF₃, CF₂CF₂OCF₂CF₃, CF₂OCF₂CF₃, CF₂OCF₂CF₂CF₂CF₃ or CF₂CF₂OCF₂CF₂CF₃.

A thickness of the first layer may be in a range of about 30 μm to about 95 μm.

A thickness of the second layer may be in a range of about 1 μm to about 10 μm.

A thickness of the third layer may be in a range of about 50 nm to about 150 nm.

A surface of the second layer may be in contact with the first layer, and another surface of the second layer may be in contact with the third layer.

A reflectivity of the cover layer may be about 1.4% to about 1.6% with respect to light of 550 nm.

A refractive index of the third layer may be in a range of 1.36 to 1.41.

A nanoindentation hardness of the cover layer may be in a range of 1.52 GPa to 1.73 GPa.

In accordance with another aspect of the present disclosure, provided is a display device including: a light emitting element layer including a light emitting element configured to emit light; and a cover layer on the light emitting element layer, wherein the cover layer includes: a first layer forming a base; a second layer disposed on the first layer, the second layer including a random-type silsesquioxane including an ether functional group; and a third layer disposed on the second layer, the third layer including a random-type silsesquioxane including a perfluoroalkyl functional group and a cage-type silsesquioxane including a fluorine-based ether functional group.

The first layer may include poly(ethylene terephthalate) (PET). The ether functional group of the second layer may include ethyl-methyl-ether group (C₂H₅OCH₃), an ether group (C₃OH₁₁) including five carbons, or an ether group (C₄OH₉) including four carbons. The perfluoroalkyl functional group of the third layer may include CF₂CF₂CF₂CF₃, CF₂CF₂CF₃ or CF₂CF₂CF₂CF₂CF₃. The fluorine-based ether functional group of the third layer may include CF₂OCF₂CF₂CF₃, CF₂CF₂OCF₂CF₃, CF₂OCF₂CF₃, CF₂OCF₂CF₂CF₂CF₃ or CF₂CF₂OCF₂CF₂CF₃.

A thickness of the first layer may be in a range of about 30 μm to about 95 μm, a thickness of the second layer may be in a range of about 1 μm to about 10 μm, and a thickness of the third layer may be in a range of about 50 nm to about 150 nm.

The third layer may be an uppermost layer of the display device.

The display device may be a flexible display device.

The random-type silsesquioxane included in the second layer may include twelve ether functional groups in one molecule.

The random-type silsesquioxane included in the third layer may include twelve fluorine-based perfluoroalkyl functional groups in one molecule.

The cage-type silsesquioxane included in the third layer may include six fluorine-based ether functional groups in one molecule.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, the example embodiments are provided such that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the present disclosure.

FIG. 2 is a schematic sectional view illustrating a display device in accordance with an embodiment of the present disclosure.

FIG. 3 is a schematic sectional view illustrating a cover layer in accordance with an embodiment of the present disclosure.

FIG. 4 is a chemical formula illustrating a material included in a second layer.

FIG. 5 is a chemical formula illustrating a first material included in a third layer.

FIG. 6 is a chemical formula illustrating a second material included in the third layer.

### DETAILED DESCRIPTION

The present disclosure may apply various changes and different shapes, and the descriptions herein illustrate in details with particular examples. However, the examples are not limited to certain shapes but apply to all suitable variations, equivalent materials, and replacements. The drawings included are illustrated a fashion where the figures are expanded for the better understanding.

It will be understood that, although the terms “first”, “second”, and the like may be used herein to describe various elements, these elements should not be limited by these terms. These terms are used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as, for example, a layer, region, substrate or plate is placed “on” or “above” another element indicates not only a case where the element is placed “directly on” or “just above” the other element but also a case where a further element is interposed between the element and the other element. On the contrary, an expression that an element such as, for example, a layer, region, substrate or plate is placed “beneath” or “below” another element indicates not only a case where the element is placed “directly beneath” or “just below” the other element but also a case where a further element is interposed between the element and the other element.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within #30%, 20%, 10%, 5% of the stated value, for example.

The present disclosure generally relates to a cover layer for a display device and a display device including the cover layer. Hereinafter, a cover layer for a display device and a display device including the cover layer in accordance with embodiments of the present disclosure will be described with reference to the accompanying drawings.

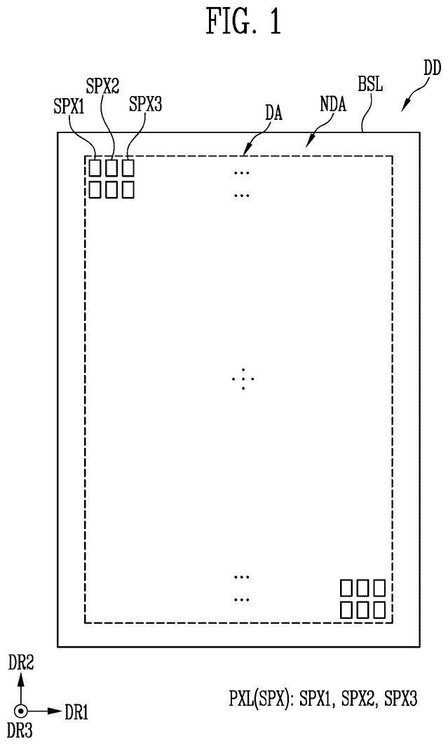

FIG. 1 is a schematic plan view illustrating a display device in accordance with an embodiment of the present disclosure.

Referring to FIG. 1, the display device DD may include a base layer BSL and pixels PXL disposed on the base layer BSL. Although not illustrated in the drawing, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA.

In some embodiments, the display device DD may be a flexible display device. For example, the display device DD may be a bendable display device, a rollable display device, or a foldable display device.

In some embodiments, the display device DD may be formed in a rectangular plane having short sides in a first direction DR1 and long sides in a second direction DR2 intersecting the first direction DR1. In some embodiments, a corner at which the short side in the first direction DR1 and the long side in the second direction DR2 meet each other may be formed such that the corner is rounded and has a predetermined curvature or be formed at a right angle. The planar shape of the display device DD is not limited to a quadrangular shape, and the display device DD may be formed in a round shape such as, for example, another polygonal shape, a circular shape, or an elliptical shape. The display device DD may be formed flat, but embodiments of the present disclosure are not limited thereto. For example, the display device DD may include a curved portion which is formed at a left/right end and has a constant curvature or a changing curvature. In some aspects, the display device DD may include a panel layer which is bendable, to be flexibly formed such that the display device DD is warpable, curvable, bendable, foldable or rollable.

In the present disclosure, the first direction DR1 may be a “horizontal” direction as a row direction of pixels PXL. The second direction DR2 may be a column direction of pixels PXL. A third direction DR3 may be a display direction of the display device DD or a normal direction of a plane on which a base layer BSL is disposed.

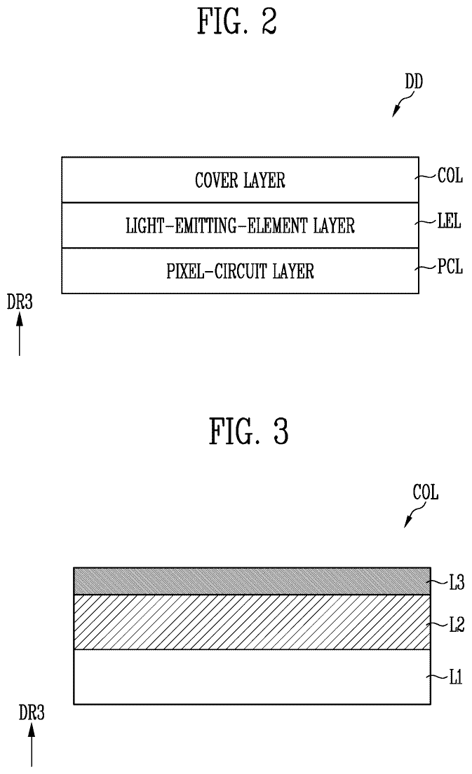

In some embodiments, the display device DD may include a cover layer COL (see FIG. 2) having excellent mechanical characteristics and flexibility. Accordingly, the display device DD may be appropriately applied to the flexible display device.

The base layer BSL may form a base surface of the display device DD. The base layer BSL may be a rigid or flexible substrate or film. For example, the base layer BSL may be a rigid substrate formed of glass or tempered glass, a flexible substrate (or thin film) formed of a plastic or metal material, or at least one insulating layer. However, the material and/or property of the base layer BSL are/is not particularly limited. In an embodiment, the base layer BSL may be substantially transparent. The term “substantially transparent” may mean that light can be transmitted with a certain transmittance or more. The term “substantially,” as used herein, means approximately or actually. In another embodiment, the base layer BSL may be translucent or opaque. The base layer BSL may include a reflective material in some embodiments.

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

In accordance with an embodiment, the pixels PXL (or sub-pixels SPX) may be arranged according to a stripe arrangement structure, a PENTILE™ arrangement structure, or the like. However, embodiments of the present disclosure are not limited thereto, and various embodiments may be applied in the present disclosure.

In accordance with an embodiment, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form one pixel unit capable of emitting lights of various colors.

For example, each of the first sub-pixel SPX1, the second sub-pixel SPX2, and the third sub-pixel SPX3 may emit light of a respective color. For example, the first sub-pixel SPX1 may be a red pixel emitting red light (e.g., the first color), the second sub-pixel SPX2 may be a green pixel emitting green light green (e.g., the second color), and the third sub-pixel SPX3 may be a blue pixel emitting blue light (e.g., the third color). In accordance with an embodiment, the number of second sub-pixels SPX2 may be greater than the number of first sub-pixels SPXL1 and the number of third sub-pixels SPXL3. However, the color, type, and/or number of first, second, and third sub-pixels SPX1, SPX2, and SPX3 constituting each pixel unit are not limited to a specific example.

FIG. 2 is a schematic sectional view illustrating a display device in accordance with an embodiment of the present disclosure.

Referring to FIG. 2, the display device DD may include a pixel circuit layer PCL (e.g., a backplane layer), a light emitting element layer LEL, and a cover layer COL.

The pixel circuit layer PCL may be a layer including a pixel circuit for driving a pixel PXL formed by the light emitting element layer LEL (or a light emitting element included in the light emitting element layer LEL). The pixel circuit layer PCL may include a base layer BSL (see FIG. 1), conductive layers for forming pixel circuits, and insulating layers disposed on the conductive layers.

The light emitting element layer LEL may be disposed on the pixel circuit layer PCL. In some embodiments, the light emitting element layer LEL may include the light emitting element. In some embodiments, the light emitting element may include an organic light emitting diode (OLED). Alternatively, in some embodiments, the light emitting element may include an inorganic light emitting element including an inorganic material. Alternatively, in some embodiments, the light emitting element layer LEL may include a Liquid Crystal Display (LCD). However, embodiments of the present disclosure are not limited thereto.

The cover layer COL may be disposed on the light emitting element layer LEL. The cover layer COL may allow light emitted from the light emitting element layer LEL to be transmitted therethrough.

The cover layer COL in accordance with embodiments of the present disclosure will be described in detail with reference to FIGS. 3 to 6.

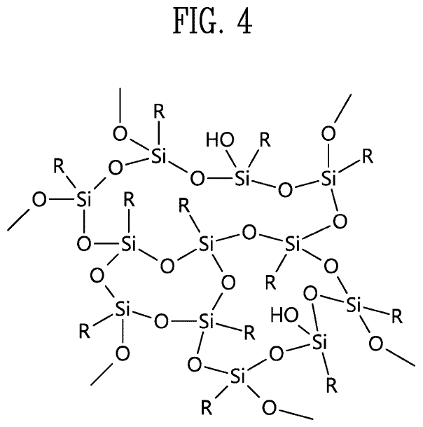

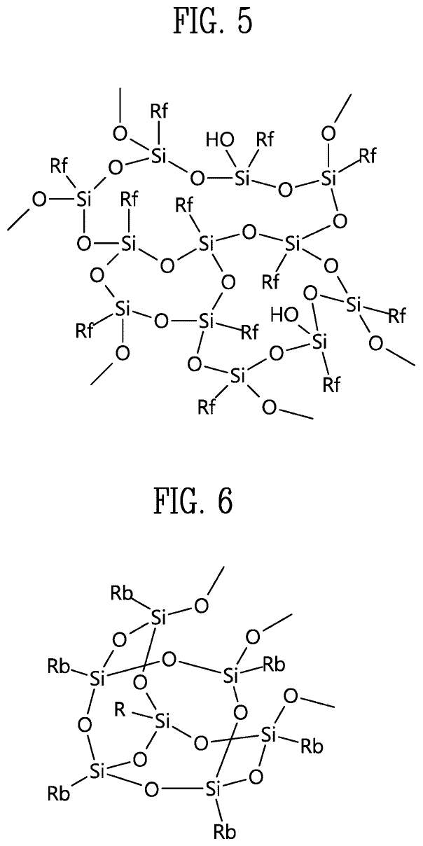

FIG. 3 is a schematic sectional view illustrating a cover layer in accordance with an embodiment of the present disclosure. FIG. 4 is a chemical formula illustrating a material included in a second layer. FIG. 5 is a chemical formula illustrating a first material included in a third layer. FIG. 6 is a chemical formula illustrating a second material included in the third layer.

Referring to FIGS. 3 to 6, the cover layer COL may include a first layer L1, a second layer L2, and a third layer L3.

The first layer L1 may be a substrate of the cover layer COL. For example, the first layer L1 may form a base on which the second layer L2 is disposed. In some embodiments, the first layer L1 may be a film type layer.

The first layer L1 may include an organic material. For example, the first layer L1 may include poly(ethylene terephthalate) (PET). However, embodiments of the present disclosure are not limited thereto.

In some embodiments, the first layer L1 may have a thickness of about 30 μm to about 95 μm. For example, the first layer L1 may have a thickness of about 65 μm. However, embodiments of the present disclosure are not limited thereto.

In accordance with an embodiment, the second layer L2 and the third layer L3 may include random-type silsesquioxanes having different functional groups, and the third layer L3 may further include a cage-type silsesquioxane including a fluorine-based ether functional group. Accordingly, the cover layer COL can simultaneously satisfy various properties required in the visibility, mechanical characteristics, and the like of the display device DD.

The random-type silsesquioxane is one of various structural examples of silsesquioxane. The random-type silsesquioxane is a siloxane material including a Si—O—Si bonding. The random-type silsesquioxane may be prepared based on a hydrolysis condensation method or the like of alkoxy or chlorosilane. However, embodiments of the present disclosure are not limited thereto.

In the random-type silsesquioxane, an organic compound and an inorganic compound may form a three-dimensional interconnect structure. The random-type silsesquioxane may be an organic-inorganic hybrid material in which the organic compound and the inorganic compound are combined with a molecular scale. Accordingly, the random-type silsesquioxane may have characteristics of the inorganic material and have characteristics of the organic material.

For example, the random-type silsesquioxane may have relatively excellent flexibility and availability as the characteristics of the organic material. In some aspects, the random-type silsesquioxane may have relatively excellent heat resistance and hardness characteristics as the characteristics of the inorganic material.

In some embodiments, since the random-type silsesquioxane may have excellent flexibility, the display device DD including the cover layer COL may be applied to the flexible display device. Accordingly, even when the display device DD is implemented as the flexible display device, the described characteristics of the COL may reduce or prevent potential risks from occurring in the display device. For example, aspects of the COL described herein may prevent or reduce that a risk will occur in mechanical behavior such as that cracks occur in the display device DD.

For example, the cover layer COL may have a crack strain of about 10% to about 15%. In some embodiments, the cover layer COL may have a crack strain of about 12.5%. The crack strain is an elongation rate as a property representing deformation resistance. The crack strain of the cover layer COL may be measured using an ordinary apparatus for measuring an elongation rate.

The cage-type silsesquioxane is one of various structural examples of silsesquioxane. The random-type silsesquioxane is a siloxane material including a Si—O—Si bonding. The cage-type silsesquioxane may have a three-dimensional structure. For example, the cage-type silsesquioxane may have a polyhedron structure.

The cage-type silsesquioxane may have relatively excellent heat resistance and hardness characteristics. Accordingly, the display device DD including the random-type silsesquioxane and the cage-type silsesquioxane can have folding reliability even when the display device DD is manufactured such that the display device DD has a curvature of about 1.5 R (e.g., even when the display device DD is manufactured to a degree to which the display device DD surround a circle having a radius of about 1.5 mm).

In the example in which the display device DD is manufactured such that the display device DD has a curvature of about 1.5 R, the display device DD may be folded 200,000 times or more at a room temperature (e.g., about 25° C.). In the example in which the display device DD is manufactured such that the display device DD has the curvature of 1.5 R, the display device DD may be folded 130,000 times or more under the condition of a temperature of about 60° C. and a humidity of about 93%. In the example in which the display device DD is manufactured such that the display device DD has the curvature of about 1.5 R, the display device DD may be folded 30,000 times or more under the condition of a temperature of about −25° C.

The second layer L2 may be disposed on the first layer L1. The second layer L2 may be disposed between the first layer L1 and the third layer L3. In some embodiments, the second layer L2 may be directly disposed on (e.g., in contact with) the first layer L1.

The second layer L2 may include a random-type silsesquioxane including an ether functional group. A chemical formula of the random-type silsesquioxane including the ether functional group is illustrated in FIG. 4. In FIG. 4, R may represent an ether group (e.g., CₙOH₂ₙ₊₁). For example, R may represent an ethyl-methyl-ether group (C₂H₅OCH₃). Alternatively, R may represent an ether group (C₃OH₁₁) including five carbons. Alternatively, R may represent an ether group (C₄OH₉) including four carbons.

The random-type silsesquioxane including the ether functional group in accordance with embodiments of the present disclosure may include twelve ether groups in one molecule. The random-type silsesquioxane including the ether functional group may include six reactive groups.

In some embodiments, the second layer L2 may be a hard coating layer. For example, as the second layer L2 includes the random-type silsesquioxane including the ether functional group, the second layer L2 may have relatively excellent flexibility while having high hardness. That is, as the second layer L2 includes the random-type silsesquioxane having excellent mechanical characteristics, the stretchability and abrasion resistance of the cover layer COL can be improved.

In some embodiments, as the second layer L2 includes the random-type silsesquioxane including the ether functional group, the second layer L2 may have excellent heat resistance.

In some embodiments, the second layer L2 may be manufactured by coating the random-type silsesquioxane forming the second layer L2 on the first layer L1. For example, the second layer L2 may be manufactured by being wet-coated on the first layer L1 and then polymerized by ultraviolet light. As the second layer L2 is manufactured according to the wet coating, the second layer L2 may be formed flat.

In some embodiments, the second layer L2 may have a thickness in a range of about 1 μm to about 10 μm. For example, the second layer L2 may have a thickness of about 5 μm.

The third layer L3 may be disposed on the second layer L2. The third layer L3 may be an uppermost layer of the cover layer COL. The third layer L3 may be an uppermost layer of the display device DD. In some embodiments, the third layer L3 may be directly disposed on (e.g., in contact with) the second layer L2.

The third layer L3 may include a random-type silsesquioxane including a perfluoroalkyl functional group (hereinafter, may be defined as a first material) and a cage-type silsesquioxane including a fluorine-based ether functional group (hereinafter, may be defined as a second material).

In some embodiments, the third layer L3 may be formed as the first material and the second material are mixed together. The third layer L3 may include the first material having a weight percentage greater than a weight percentage of the second material. For example, a wt % of the first material included in the third layer L3 may be greater than a wt % of the second material included in the third layer L3.

The wt % of the first material included in the third layer L3 may be about 70 wt % to about 90 wt %. The wt % of the second material included in the third layer L3 may be about 10 wt % to about 30 wt %. In some embodiments, with respect to the whole of the third layer L3, the wt % of the first material in the third layer L3 may be about 80 wt %, and the wt % of the second material in the third layer L3 may be about 20 wt %. In some embodiments, with respect to the whole of the third layer L3, the wt % of the first material in the third layer L3 may be about 70 wt %, and the wt % of the second material in the third layer L3 may be about 30 wt % L3. In some embodiments, with respect to the whole of the third layer L3, the wt % of the first material in the third layer L3 may be y about 90 wt %, and the wt % of the second material in the third layer L3 may be about 10 wt %.

As the first material and the second material are included in the display device DD by the numerical ranges described herein, the display device DD (or the cover layer COL) may have relatively high hardness and have high folding reliability. For example, regarding the display device DD, the display device DD (or the cover layer COL) may have a nanoindentation hardness of about 1.52 GPa to about 1.73 GPa.

A chemical formula of the random-type silsesquioxane including the perfluoroalkyl functional group is illustrated in FIG. 5. In FIG. 5, Rf may represent a fluorine-based perfluoroalkyl functional group (e.g., CₙF₂ₙ₊₁). For example, Rf may include a fluorine-based perfluoroalkyl functional group including four carbons (CF₂CF₂CF₂CF₃). Alternatively, Rf may include a fluorine-based perfluoroalkyl functional group including three carbons (CF₂CF₂CF₃). Alternatively, Rf may include a fluorine-based perfluoroalkyl functional group including five carbons (CF₂CF₂CF₂CF₂CF₃).

The random-type silsesquioxane including the perfluoroalkyl functional group in accordance with embodiments of the present disclosure may include twelve fluorine-based perfluoroalkyl functional groups in one molecule. The random-type silsesquioxane including the perfluoroalkyl functional group may include six reactive groups.

A chemical formula of a cage-type silsesquioxane including a fluorine-based ether functional group is illustrated in FIG. 6. In FIG. 6, Rb may represent a fluorine-based ether functional group (e.g., CₙOF₂ₙ₊₁). For example, Rb may include a fluorine-based ether functional group (C₄OF₉) including four carbons (e.g., CF₂OCF₂CF₂CF₃ or CF₂CF₂OCF₂CF₃). Alternatively, Rb may include a fluorine-based ether functional group including three carbons (CF₂OCF₂CF₃). Alternatively, Rb may include a fluorine-based ether functional group including five carbons (CF₂OCF₂CF₂CF₂CF₃ or CF₂CF₂OCF₂CF₂CF₃).

In FIG. 6, R may represent the above-described ether functional group (e.g., CₙOH₂ₙ₊₁). For example, R may include an ethyl-methyl-ether group (C₂H₅OCH₃). Alternatively, R may include an ether group including five carbons (C₅OH₁₁). Alternatively, R may include an ether group including four carbons (C₄OH₉).

The cage-type silsesquioxane including the fluorine-based ether functional group in accordance with embodiments of the present disclosure may include six fluorine-based ether functional groups in one molecule. The cage-type silsesquioxane including the fluorine-based ether functional group may include three reactive groups.

In some embodiments, the third layer L3 may have a thickness in a range of about 50 nm to about 150 nm. The third layer L3 may have a thickness in a range of about 80 nm to about 120 nm. For example, the third layer L3 may have a thickness of about 100 nm.

In some embodiments, the third layer L3 may be a low refractive layer. For example, the third layer L3 may have a low refractive index in comparison to the second layer L2. In some embodiments, the refractive index of the third layer L3 may be in a range of about 1.35 to about 1.41. In some embodiments, the refractive index of the third layer L3 may be about 1.39. In some embodiments, the refractive index of the third layer L3 may be about 1.38.

In some embodiments, the third layer L3 may have a reflection characteristic. For example, a reflectivity of the cover layer COL including the third layer L3 may be about 1.4% to about 1.6%. For example, the reflectivity of the cover layer COL including the third layer L3 may be about 1.42% and be about 1.51%. The reflectivity of the cover layer COL including the third layer L3 may be specified with respect to that the thickness of the third layer L3 is about 100 nm and the wavelength of applied light is 550 nm. However, embodiments of the present disclosure are not limited thereto.

Accordingly, the third layer L3 may have a low reflection characteristic with respect to external light, and the third layer L3 may decrease the external light reflectivity of the display device DD. Thus, a risk that the visibility will be damaged due to external light can be reduced, and the display device DD having improved visibility is provided. Consequently, the display device DD in accordance with embodiments of the present disclosure can be provide to be applicable to the flexible display device while having high visibility.

In some embodiments, the third layer L3 may be manufactured by being deposited on the second layer L2. Since the reactivity of the random-type silsesquioxane is excellent, and each of the random-type silsesquioxane and the cage-type silsesquioxane includes a functional group including carbons, the third layer can be efficiently manufactured through a vacuum deposition polymerization process.

In some embodiments, the third layer L3 may be an anti-fingerprint layer. In some embodiments, a top surface of the third layer L3 may be exposed. The top surface of the third layer L3 may include an area in which a touch event may occur when a body (or body part, for example, a finger) of a user of the display device DD is in contact therewith. In accordance with an embodiment, the third layer L3 disposed at a relatively upper side of the display device DD may include a silsesquioxane including a fluorine-based functional group (e.g., a perfluoroalkyl functional group and a fluorine-based ether functional group). Accordingly, the third layer L3 may have excellent abrasion resistance and friction resistance characteristics, and serve as the anti-fingerprint layer. Thus, in some embodiments, the display device DD may be implemented without any additional layer for implementing the anti-fingerprint layer, and process costs can be reduced.

Consequently, as the display device DD in accordance with embodiments of the present disclosure includes the cover layer COL including the second layer L2 including the random-type silsesquioxane and the third layer L3 including the random-type and cage-type silsesquioxanes including the fluorine-based functional group, display quality can be improved, and mechanical characteristics can be improved. Accordingly, the display device DD applicable to various flexible devices can be provided.

In accordance with embodiments of the present disclosure, provided is a cover layer and a display device including the cover layer, in which external light reflectivity is controlled, such that visibility is improved.

In accordance with embodiments of the present disclosure, provided is a cover layer and a display device including the cover layer, which have excellent mechanical characteristics and flexibility.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A cover layer for a display device, the cover layer comprising:
a first layer forming a base;
a second layer disposed on the first layer, the second layer comprising a random-type silsesquioxane comprising an ether functional group; and
a third layer disposed on the second layer, the third layer comprising:
a random-type silsesquioxane comprising a perfluoroalkyl functional group; and
a cage-type silsesquioxane comprising a fluorine-based ether functional group.

2. The cover layer of claim 1, wherein the first layer comprises poly(ethylene terephthalate) (PET).

3. The cover layer of claim 1, wherein the ether functional group of the second layer comprises an ethyl-methyl-ether group (C₂H₅OCH₃), an ether group (C₃OH₁₁) comprising five carbons, or an ether group (C₄OH₉) comprising four carbons.

4. The cover layer of claim 1, wherein the perfluoroalkyl functional group of the third layer comprises CF₂CF₂CF₂CF₃, CF₂CF₂CF₃ or CF₂CF₂CF₂CF₂CF₃.

5. The cover layer of claim 1, wherein the fluorine-based ether functional group of the third layer comprises CF₂OCF₂CF₂CF₃, CF₂CF₂OCF₂CF₃, CF₂OCF₂CF₃, CF₂OCF₂CF₂CF₂CF₃ or CF₂CF₂OCF₂CF₂CF₃.

6. The cover layer of claim 1, wherein a thickness of the first layer is in a range of about 30 μm to about 95 μm.

7. The cover layer of claim 1, wherein a thickness of the second layer is in a range of about 1 μm to about 10 μm.

8. The cover layer of claim 1, wherein a thickness of the third layer is in a range of about 50 nm to about 150 nm.

9. The cover layer of claim 1, wherein:
a surface of the second layer is in contact with the first layer, and
another surface of the second layer is in contact with the third layer.

10. The cover layer of claim 1, wherein a reflectivity of the cover layer is about 1.4% to about 1.6% with respect to light of 550 nm.

11. The cover layer of claim 1, wherein a refractive index of the third layer is in a range of about 1.36 to about 1.41.

12. The cover layer of claim 1, wherein a nanoindentation hardness of the cover layer is in a range of about 1.52 GPa to about 1.73 GPa.

13. A display device comprising:
a light emitting element layer comprising a light emitting element configured to emit light; and
a cover layer on the light emitting element layer,
wherein the cover layer comprises:
a first layer forming a base;
a second layer disposed on the first layer, the second layer comprising a random-type silsesquioxane comprising an ether functional group; and
a third layer disposed on the second layer, the third layer comprising:
a random-type silsesquioxane comprising a perfluoroalkyl functional group; and
a cage-type silsesquioxane comprising a fluorine-based ether functional group.

14. The display device of claim 13, wherein:
the first layer comprises poly(ethylene terephthalate) (PET),
the ether functional group of the second layer comprises ethyl-methyl-ether group (C₂H₅OCH₃), an ether group (C₃OH₁₁) comprising five carbons, or an ether group (C₄OH₉) comprising four carbons,
the perfluoroalkyl functional group of the third layer comprises CF₂CF₂CF₂CF₃, CF₂CF₂CF₃ or CF₂CF₂CF₂CF₂CF₃, and
the fluorine-based ether functional group of the third layer comprises CF₂OCF₂CF₂CF₃, CF₂CF₂OCF₂CF₃, CF₂OCF₂CF₃, CF₂OCF₂CF₂CF₂CF₃ or CF₂CF₂OCF₂CF₂CF₃.

15. The display device of claim 13, wherein:
a first thickness of the first layer is in a range of about 30 μm to about 95 μm,
a second thickness of the second layer is in a range of about 1 μm to about 10 μm, and
a third thickness of the third layer is in a range of about 50 nm to about 150 nm.

16. The display device of claim 13, wherein the third layer is an uppermost layer of the display device.

17. The display device of claim 13, wherein the display device is a flexible display device.

18. The display device of claim 13, wherein the random-type silsesquioxane comprised in the second layer comprises twelve ether functional groups in one molecule.

19. The display device of claim 13, wherein the random-type silsesquioxane comprised in the third layer comprises twelve fluorine-based perfluoroalkyl functional groups in one molecule.

20. The display device of claim 13, wherein the cage-type silsesquioxane comprised in the third layer comprises six fluorine-based ether functional groups in one molecule.
